(19) United States
(12) Patent Application Publication
(10) Pub. No.: US 2012/0193784 A1
(43) Pub. Date: Aug. 2, 2012

(54) METHOD FOR JOINING BONDING WIRE, SEMICONDUCTOR DEVICE, AND METHOD FOR MANUFACTURING SEMICONDUCTOR DEVICE

(75) Inventors: Norihiro Togasaki, Kawasaki-shi (JP); Mitsuhiro Nakao, Yokohama-shi (JP); Yosuke Morita, Yokkaichi-shi (JP)

(73) Assignee: KABUSHIKI KAISHA TOSHIBA, Tokyo (JP)

(21) Appl. No.: 13/353,535

(22) Filed: Jan. 19, 2012

(30) Foreign Application Priority Data
Jan. 31, 2011 (JP) 2011-018811

(51) Int. Cl. H01L 23/498; H01L 21/60

(52) U.S. Cl. 257/737; 438/613; 257/E21.508; 257/E23.068

(57) ABSTRACT

Provided is a method for joining a bonding wire, the method including wedge-joining a bonding wire which has a core whose main component is a non-noble metal and a noble metal layer covering the core to a bump formed on an electrode of a semiconductor element via the noble metal layer.

### CROSS-REFERENCE TO RELATED APPLICATION

This application is based upon and claims the benefit of priority from the prior Japanese Patent Application No. 2011-018811, filed on Jan. 31, 2011; the entire contents of which are incorporated herein by reference.

### FIELD

Embodiments described herein relate generally to a method for joining a bonding wire, a semiconductor device, and a method for manufacturing a semiconductor device.

### BACKGROUND

In a conventional semiconductor device, an electrode (pad) on a semiconductor chip and a lead of a lead frame are electrically connected by a bonding wire (hereinafter, described as a noble metal wire) whose main component is a noble metal (for example, gold (Au)). However, as a noble metal price increases in recent years, a bonding wire (hereinafter, described as a non-noble metal wire) whose main component is a non-noble metal (for example, copper (Cu)) which is less expensive begins to be used for connecting an electrode on a semiconductor chip and an electrode of a lead frame.

### BRIEF DESCRIPTION OF THE DRAWINGS

FIG. 1 is a cross-sectional view of a semiconductor device according to an embodiment.

FIG. 2 is a cross-sectional view of a bonding wire.

FIG. 3A to FIG. 3G are explanatory diagrams of reverse bonding processes.

FIG. 4A to FIG. 4E are explanatory diagrams of a first capillary action.

FIG. 5A is an SEM image of a bump formed by the first action of a capillary.

FIG. 5B is an enlarged view of the bump formed by the first action of the capillary.

FIG. 5C is across-sectional SEM image of the bump formed by the first action of the capillary.

FIG. 5D is cross-sectional SEM image of the bump formed by the first action of the capillary.

FIG. 6A to FIG. 6G are explanatory diagrams of a second action of a capillary.

FIG. 7A is an SEM image of a bump formed by the second action of the capillary.

FIG. 7B is an enlarged view of the bump formed by the second action of the capillary.

FIG. 8A and FIG. 8B are explanatory diagrams of a method for cutting a bonding wire.

FIG. 9 is one example of a cross-sectional view of a semiconductor device according to another embodiment.

FIG. 10 is another example of a cross-sectional view of a semiconductor device according to another embodiment.

FIG. 11A is an SEM image of a state in which bonding is performed on a wedge joint.

FIG. 11B is an enlarged view of the state in which bonding is performed on the wedge joint.

FIG. 12 is another example of a cross-sectional view of a semiconductor device according to another embodiment.

FIG. 13A is a cross-sectional SEM image of a bump and a bonding wire according to an example.

FIG. 13B is a cross-sectional SEM image of a bump and a bonding wire according to a comparative example.

### DETAILED DESCRIPTION

In a method for joining a bonding wire according to an embodiment, a bonding wire that has a core whose main component is a non-noble metal and a noble metal layer covering the core is wedge-joined to a bump formed on an electrode on a semiconductor element via the noble metal layer.

Hereinafter, the embodiment will be described with reference to the drawings.

### Embodiment

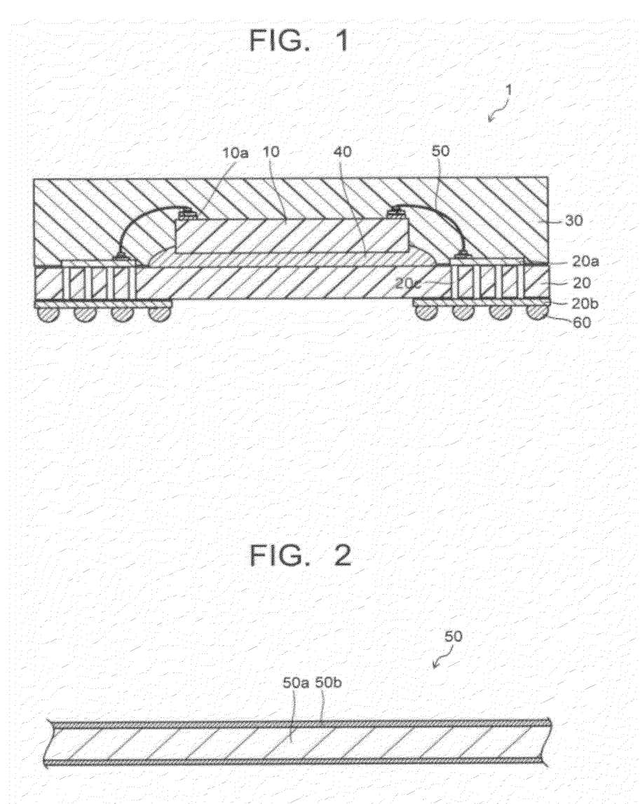

FIG. 1 is a cross-sectional view of a semiconductor device 1 according to the embodiment. Hereinafter, a configuration of the semiconductor device 1 according to the embodiment will be described with reference to FIG. 1.

### Configuration of Semiconductor Device 1

The semiconductor device 1 according to the embodiment has a semiconductor chip 10, a mounting substrate 20 to mount the semiconductor chip 10 thereon, and a sealing resin (molding resin) 30 which seals the semiconductor chip 10.

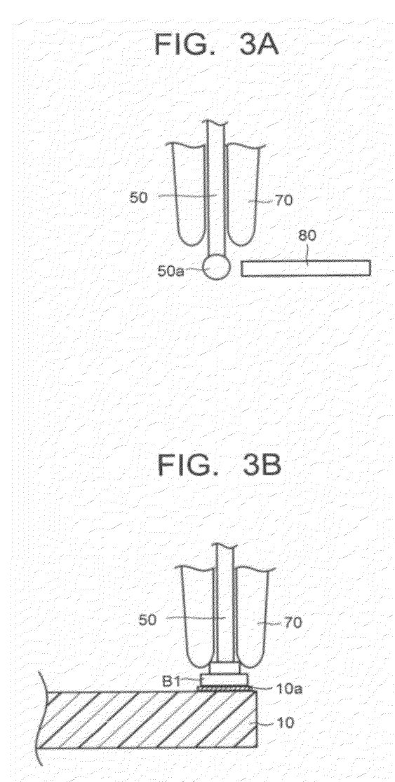

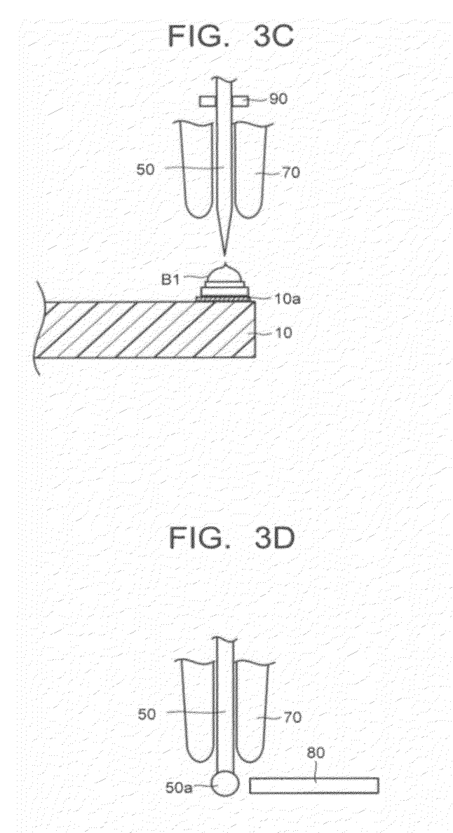

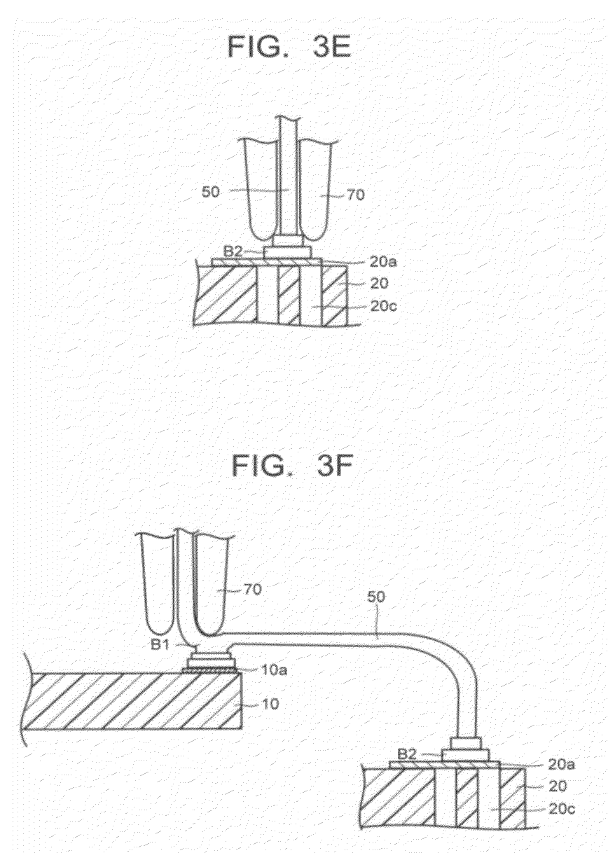

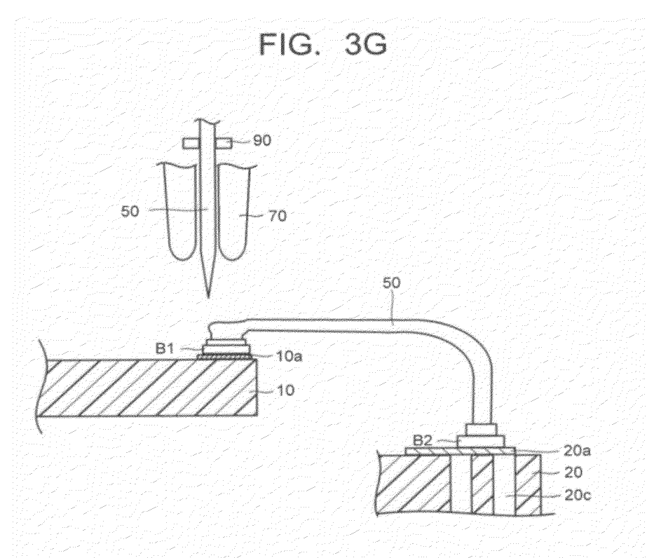

The semiconductor chip 10 is joined onto a front surface of the mounting substrate 20 by a mounting material 40 such as a solder. An electrode (pad) 10a for signal input/output formed on the semiconductor chip 10 is connected to a front surface wiring 20a formed on the mounting substrate 20 by a bonding wire 50. A method for connecting the bonding wire 50 will be described later with reference to FIG. 3A to FIG. 3G.

FIG. 2 illustrates a cross section of the bonding wire 50. As illustrated in FIG. 2, the bonding wire 50 has a core 50a whose main component is an inexpensive non-noble metal (for example, copper (Cu), aluminum (Al), or nickel (Ni)) and which is superior in electric conductivity, and a noble metal layer 50b whose main component is a noble metal (for example, palladium (Pd), platinum (Pt), or gold (Au)) superior in oxidation resistance and which covers the core 50a.

The main component means that in a case of the core 50a an inevitable impurity other than a non-noble metal can be contained. The main component means that in a case of the noble metal layer 50b an inevitable impurity other than a noble metal can be included.

The mounting substrate 20 is, for example, a printed wiring board (glass epoxy sheet) such as an FR4 (Flame Retardant Type 4), for example. As a main component of the mounting substrate 20, there can be used, other than FR4, a resin substrate such as of an ethylene tetrafluoride resin, or a ceramics substrate such as of alumina (Al₂O₃) or aluminum nitride (AlN).

In the mounting substrate 20, there are formed the front surface wiring 20a and a rear surface wiring 20b which are metal wirings, and a through hole 20c connecting the front surface wiring 20a and the rear surface wiring 20b. An inner surface of the through hole 20c is covered by an electric conductor such as a metal, and the front surface wiring 20a and the rear surface wiring 20b are electrically connected.

A BGA (ball grid array) 60 is formed on a rear surface of the mounting substrate 20. The BGA 60 is electrically connected to the electrode 10a of the semiconductor chip 10 via the rear surface wiring 20b, the through hole 20c, the front surface wiring 20a, and the bonding wire 50. Instead of the BGA 60, an LGA (land grid array) can be formed on the rear surface of the mounting substrate 20.

### Bonding Process

FIG. 3A to FIG. 3G are explanatory diagrams of bonding processes to connect an electrode 10a of a semiconductor 10 and a front surface wiring 20a of a mounting substrate 20 which a semiconductor 1 according to the embodiment has. Hereinafter, the bonding processes of the electrode 10a of the semiconductor chip 10 and the front surface wiring 20a of the mounting substrate 20 will be described with reference to FIG. 3A to FIG. 3G.

In this embodiment, the electrode 10a of the semiconductor chip 10 and the front surface wiring 20a of the mounting substrate 20 are electrically connected by what is called reverse bonding in which after a bump B1 is formed on the electrode 10a of the semiconductor chip 10, a bonding wire 50 one end of which is joined to the front surface wiring 20a of the mounting substrate 20 is wedge-joined to the bump B1 formed on the electrode 10a of the semiconductor chip 10.

### First Process: See FIG. 3A

A tip of the bonding wire 50 inserted into a capillary 70 is sparked by a spark rod 80, so that a ball 50a is formed.

### Second Process: See FIG. 3B

The capillary 70 descends onto the electrode 10a of the semiconductor chip 10, and the bump B1 is formed and joined on the electrode 10a.

### Third Process: See FIG. 3C

After joining of the bump B1, the capillary 70 ascends in a state in which a wire clamp 90 is holding the bonding wire 50, so that the bonding wire 50 is cut.

### Fourth Process: See FIG. 3D

A tip of the bonding wire 50 which has been cut is sparked by the spark rod 80, so that a ball 50a is formed.

### Fifth Process: See FIG. 3E

After the capillary 70 moves to above the front surface wiring 20a of the mounting substrate 20, the capillary 70 descends and a bump B2 is formed and joined on the front surface wiring 20a.

### Sixth Process: See FIG. 3F

When the bump B2 is joined, the capillary 70 moves to above the electrode 10a of the semiconductor chip 10. Thereafter, the capillary 70 descends onto the electrode 10a of the semiconductor chip 10 and the bonding wire 50 is wedge-joined to the bump B1 formed on the electrode 10a.

### Seventh Process: See FIG. 3G

When the bonding wire 50 is joined to the bump B1, the capillary 70 ascends in a state in which the wire clamp 90 is holding the bonding wire 50, so that the bonding wire 50 is cut.

A remaining electrode 10a of the semiconductor chip 10 is joined to a front surface wiring 20a by a bonding wire 50 similarly to in the first to seventh processes.

### First Action of Capillary 70

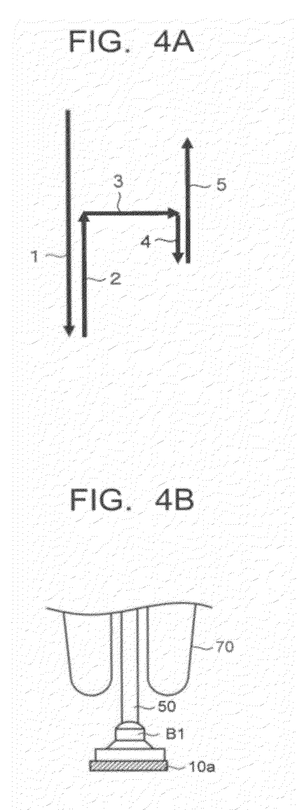

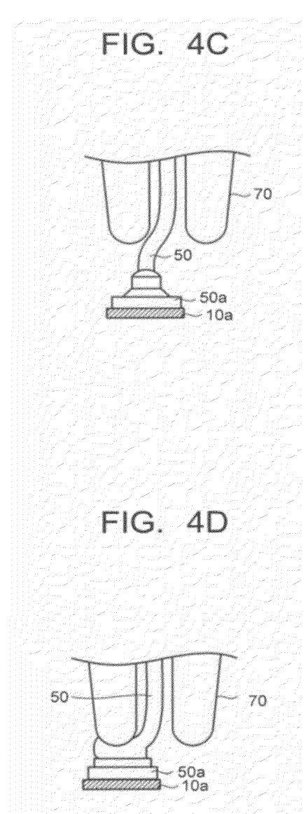

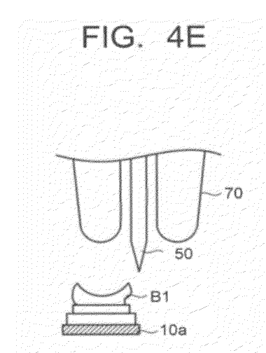

FIG. 4A to FIG. 4E are explanatory diagrams of a first action of a capillary 70 at a time of forming a bump B1. FIG. 4A is a diagram showing a trail of a tip of the capillary 70. The numbers of arrows of FIG. 4A indicate order of the action of the capillary 70. Further, FIG. 4B to FIG. 4E are diagrams illustrating states of the capillary 70 and the bump B1 in the numbers 2 to 5 of the arrows. Hereinafter, the first action of the capillary 70 will be described with reference to FIG. 4A to FIG. 4E.

### First Process: See FIG. 4B

After the capillary 70 descends onto an electrode 10a of a semiconductor chip 10 and a bump B1 is formed and joined on the electrode 10a, the capillary 70 ascends.

### Second Process: See FIG. 4C

The capillary 70 moves horizontally to a side (right side in FIG. 4C) opposite to a front surface wiring 20a of a mounting substrate 20 being a connection destination.

### Third Process: See FIG. 4D

The capillary 70 descends onto the electrode 10a of the semiconductor chip 10 and presses and joins a bonding wire 50 in a manner to fold the bonding wire 50, to an upper surface of the bump B1 having been joined in the above-described first process, by a left side of a tip of the capillary 70.

### Fourth Process: See FIG. 4E

The capillary 70 ascends in a state in which a not-shown wire clamp is holding the bonding wire 50, so that the bonding wire 50 is cut.

### Form of Bump B1

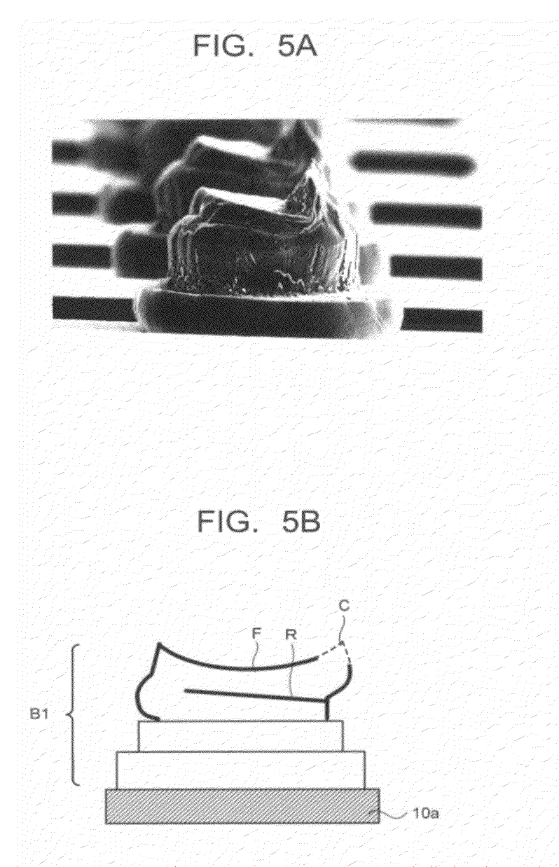

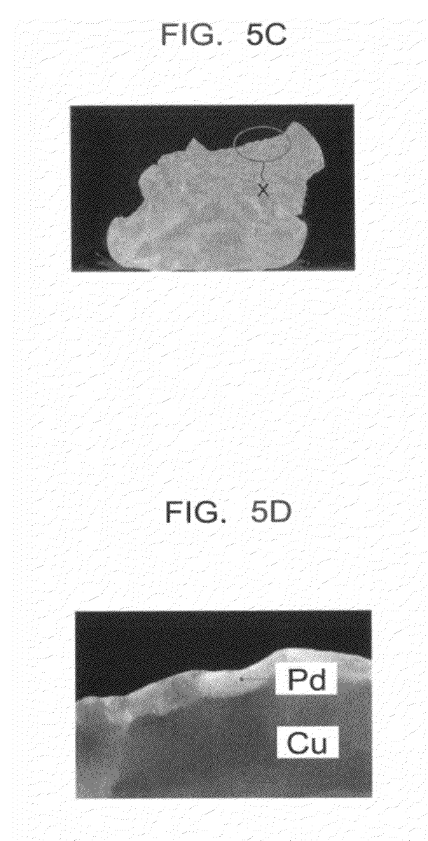

FIG. 5A is an SEM image of the bump B1 formed by the first action described with reference to FIG. 4A to FIG. 4E. FIG. 58 is an enlarged view of the bump B1 formed by the first action described with reference to FIG. 4A to FIG. 4E. It should be noted that, in FIG. 5B, in the bump B1 a part where a noble metal layer 50b covering a core 50a exists is indicated by a bold solid line while a part where the noble metal layer 50b does not exist is indicated by a broken line.

In the first action described with reference to FIG. 4A to FIG. 4E, since the bonding wire 50 is pressed and joined, in a manner to be folded, to the upper surface of the bump B1 having been joined in the first process, the bump B1 is formed on the electrode 10a of the semiconductor chip 10 in a state in which at least a part of an upper surface F is covered by the noble metal layer 50b.

FIG. 5C is a cross-sectional SEM image of the bump B1 formed by the first action described with FIG. 4A to FIG. 4E. In FIG. 5C, a part where the noble metal layer (palladium (Pd) in FIG. 5C) exists on the upper surface of the bump B1 is indicated by a chain line. FIG. 5D is an enlarged image of a region X of FIG. 5C. It is known from the SEM images shown in FIG. 5C and FIG. 5D that folding the bonding wire 50 enables formation of the bump B1 in a state in which at least a part of the upper surface F is covered by the noble metal layer 50b.

As described above, as a result that the bump B1 is formed by making the capillary 70 act according to the first action, at least a part of the upper surface F of the bump B1 is covered by the noble metal layer 50b. Thus, when the bonding wire 50 having been looped is to be wedge-joined onto the bump B1, the metal layers 50b whose main components are noble metals are joined to each other, instead of the cores 50a whose main components are non-noble metals. Hence, a sufficient joining strength can be obtained in wedge-joining a bonding wire 50 onto an upper surface of a bump B1, so that reliability of joining is improved. As a result, it is possible to suppress an occurrence of a poor condition such as joint peeling or a fracture of a bonding wire 50 at a time of a continuous bonding operation.

It is preferable that a film thickness of the noble metal layer 50b

is equal to or more than 10 nm. As described with reference to FIG. 4A to FIG. 4E, in this embodiment, the bump B1 is formed on the electrode 10a of the semiconductor chip 10 in a manner that the bonding wire 50 is folded. On this occasion, since the bonding wire 50 is crushed by a tip portion of the capillary 70, there is an apprehension that the core 50a is exposed if the noble metal layer 50b is thin. If the core 50a is exposed, because of the fact that the core 50a is not made of a noble metal, there is an apprehension that a surface thereof is oxidized and that a sufficient joining strength cannot be obtained in wedge-joining the bonding wire 50 onto the bump B1, causing an occurrence of a poor condition such as wire peeling.

In the first action, in the third process (see FIG. 4D), the bonding wire 50 is pressed and joined in a manner to be folded, and also in a joined surface R made by folding, the noble metal layers 50b whose main components are noble metals are joined to each other. Thus, a sufficient joining strength can be obtained, so that an occurrence of a poor condition such as joint peeling or a fracture of a bonding wire 50 at a time of the continuous bonding operation or the like can be suppressed.

Since an area of the upper surface F of the bump B1 formed by pressing and joining the bonding wire 50 in a manner to be folded can be made large, a joining strength of wedge joining becomes higher. Further, since energy (for example, a thermal energy or an ultrasonic output energy) at a time of joining is unnecessary to be increased in order to suppress wire peeling, so that a damage given to the semiconductor chip 10 can be suppressed.

As a result that the bonding wire 50 is pressed and joined in a manner to be folded, the bump B1 to be formed becomes high. In addition, the bonding wire 50 is folded to the side opposite to a side of the front surface wiring 20a of the mounting substrate 20 being the connection destination, that is, to the side opposite to a side toward which the bonding wire 50 is stretched, and then the bump B1 is formed. Therefore, it is possible to effectively decrease an apprehension that the bonding wire 50 looped from the front surface wiring 20a of the mounting substrate 20 contacts an upper surface end portion of the semiconductor chip 10.

When the bump B1 is formed on the electrode 10a of the semiconductor chip 10, an alloy of the noble metal (for example, palladium (Pd), platinum (Pt), gold (Au)) being the main component of the noble metal layer 50b of the bonding wire 50 and a metal (for example, Cu, Al, Al—Si, Al—Si—Cu) being a main component of the electrode 10a is formed in an interface with the bump B1 on the electrode 10a. Since this alloy is chemically stable, it is possible to heighten joining reliability of the electrode 10a of the semiconductor chip 10 and the bump B1, even in a case that a halogen series molding resin such as Br is used for a sealing material of the semiconductor chip 10.

### Second Action of Capillary 70

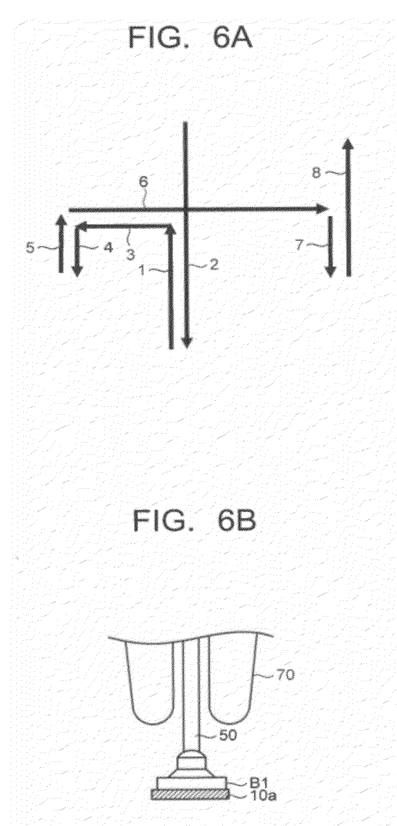

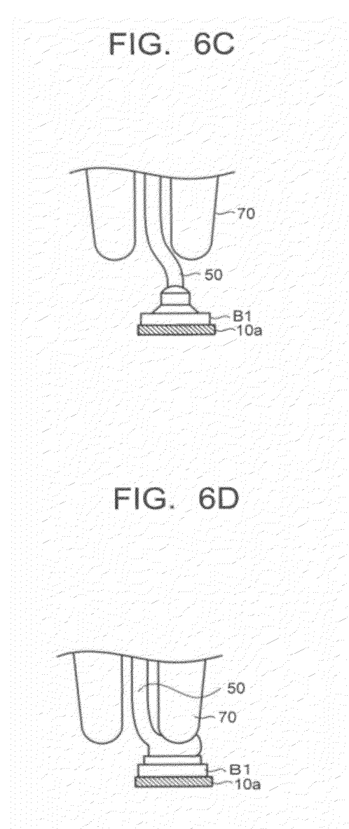

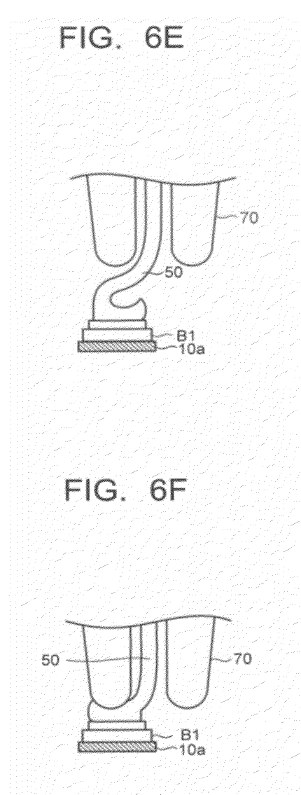

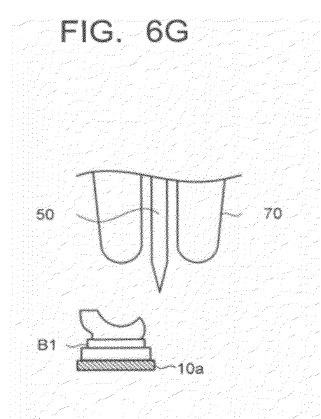

FIG. 6A to FIG. 6G are explanatory diagrams showing a second action of a capillary 70 at a time of forming a bump B1. FIG. 6A is a diagram showing a trail of a tip of the capillary 70. The numbers of arrows of FIG. 6A indicate order of the action of the capillary 70. Further, FIG. 6B to FIG. 6G are diagrams illustrating states of the capillary 70 and the bump B1 in the numbers 2 to 4 and 6 to 8 of the arrows. Hereinafter, the second action of the capillary 70 will be described with reference to FIG. 6A to FIG. 6G.

### First Process: See FIG. 6B

After the capillary 70 descends onto an electrode 10a of a semiconductor chip 10 and the bump B1 is formed and joined on the electrode 10a, the capillary 70 ascends.

### Second Process: See FIG. 6C

The capillary 70 moves horizontally in a direction (left side in FIG. 6C) of a front surface wiring 20a of amounting substrate 20 being a connection destination.

### Third Process: See FIG. 6D

The capillary 70 descends onto the electrode 10a of the semiconductor chip 10 and presses and joins a bonding wire 50 in a manner to fold the bonding wire 50, to an upper surface of the bump B1 having been joined in the above-described first process, by a right side of the tip of the capillary 70.

### Fourth Process: See FIG. 6E

After the capillary 70 ascends, the capillary 70 moves horizontally to a side (right side in FIG. 6E) opposite to the front surface wiring 20a of the mounting substrate 20 being the connection destination.

### Fifth Process: See FIG. 6F

The capillary 70 descends onto the electrode 10a of the semiconductor chip 10, and presses and joins the bonding wire 50 onto the bonding wire 50 having been joined in the above-described third process in a manner to further fold the bonding wire 50, by a left side of the tip of the capillary 70.

### Sixth Process: See FIG. 6G

The capillary 70 ascends in a state that a not-shown wire clamp is holding the bonding wire 50, so that the bonding wire 50 is cut.

### Form of Bump B1

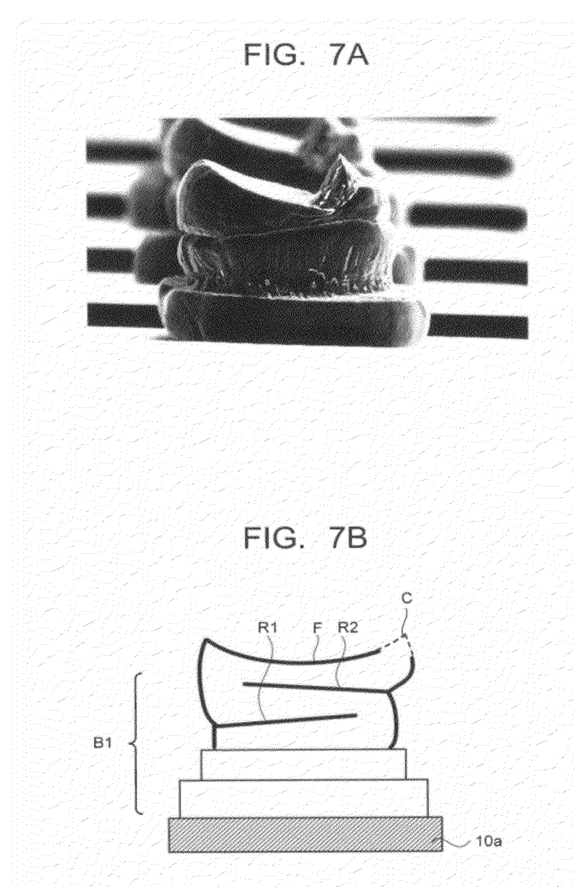

FIG. 7A is an SEM image of the bump B1 formed by the second action described with reference to FIG. 6A to FIG. 6G. FIG. 7B is an enlarged view of the bump B1 formed by the second action described with reference to FIG. 6A to FIG. 6G. It should be noted that, in FIG. 7B, in the bump B1 a part where a noble metal layer 50b covering a core 50a exists is indicated by a bold solid line while a part where the noble metal layer 50b does not exist is indicated by a broken line.

In the second action described with reference to FIG. 6A to FIG. 6G, the bonding wire 50 is pressed and joined, in a manner to be folded twice, to the upper surface of the bump B1 having been joined in the first process. Thus, compared with in the first action described with reference to FIG. 4A to FIG. 4E, an area of an upper surface F of the formed bump B1 is large. Therefore, a higher joining strength can be obtained in wedge-joining at a time of what is called reverse bonding.

Since the bonding wire 50 is pressed and joined in a manner to be folded twice, the formed bump B1 becomes higher. In addition, second folding of the bonding wire 50 is done to a side opposite to a side of the front surface wiring 20a of the mounting substrate 20 being the connection destination, that is, to a side opposite to a side toward which the bonding wire 60 is stretched. Therefore, it is possible to decrease an apprehension more effectively that the bonding wire 50 looped from the front surface wiring 20a of the mounting substrate 20 contacts an upper surface end portion of the semiconductor chip 10.

In joined surfaces R1, R2 by folding also, since the noble metal layers 50a whose main components are noble metals are joined to each other, a sufficient joining strength can be obtained. Other effects are the same as those in the first action.

### Method for Cutting Bonding Wire 50

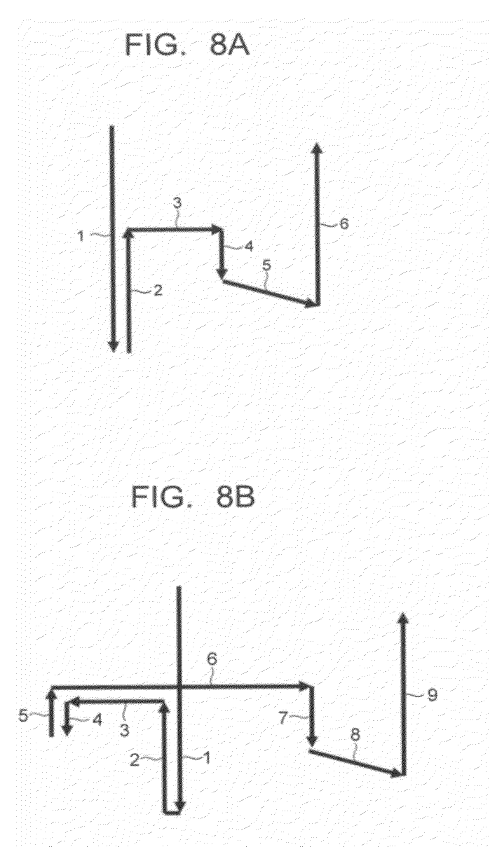

Here, a method for cutting a bonding wire 50 after formation of a bump B1 will be described with reference to FIG. 8A and FIG. 8B. First, an action of a capillary 70 will be described with reference to FIG. 8A. The numbers of arrows of FIG. 8A indicate order of the action of the capillary 70. The action of an arrow 1 to an arrow 4 shown in FIG. 8A is the same as the action of the first process to the third process described with reference to FIG. 4A and FIG. 4B to FIG. 4D, and redundant explanation will be omitted.

In the third process of FIG. 4D, after a bonding wire 50 is pressed and joined to an upper surface of the bump B1 in a manner to be folded, as shown in an arrow 5 of FIG. 8A, the capillary 70 is moved diagonally right downward, and as shown by an arrow 6 of FIG. 8A the capillary 70 is made to ascend in a state in which a not-shown wire clamp is holding the bonding wire 50.

Next, an action of a capillary 70 will be described with reference to FIG. 8B. The numbers written in FIG. 8B indicate order of the action of the capillary 70. The action of an arrow 1 to an arrow 7 shown in FIG. 8B is the same as the action of the first process to the fifth process described with reference to 6A to 6F, and redundant explanation will be omitted.

In the fifth process of FIG. 6F, after the bonding wire 50 is pressed and joined, in a manner to be folded, to the upper surface of the bump b1, as shown by an arrow 8 of FIG. 8B the capillary 70 is moved diagonally right downward, and as shown by an arrow 9 of FIG. 8B the capillary 70 is made to ascend in a state in which a not-shown wire clamp is holding the bonding wire 50.

In the first and second actions described with reference to FIG. 4A to FIG. 4E and FIG. 6A to FIG. 6G, after the bump B1 is formed on the electrode 10a of the semiconductor chip 10, the capillary 70 is made to ascend from an unchanged position thereby to cut the bonding wire 50. However, as described above, by moving the capillary 70 diagonally right downward (or diagonally left downward) and thereafter making the capillary 70 ascend thereby to cut the bonding wire 50, an area of a cross section formed on an upper surface of the bump B1 can be made small.

Thus, it is possible to make an area in which the noble metal layer 50b exists on the upper surface of the bump B1 where the bonding wire 50 is to be wedge-joined larger, so that a stronger joining strength can be obtained. As a result, it is possible to suppress an occurrence of a poor condition such as joint peeling or a fracture of a bonding wire 50 in a continuous bonding operation or the like more effectively.

### Other Embodiments

In the embodiment, there is described a mode in which the bonding wire 50 looped from the front surface wiring 20a of the mounting substrate 20 is wedge-joined to the bump B1 formed on the electrode 10a of the semiconductor chip 10 in the semiconductor device 1 (see FIG. 1) according to the embodiment, but application to other modes is also possible.

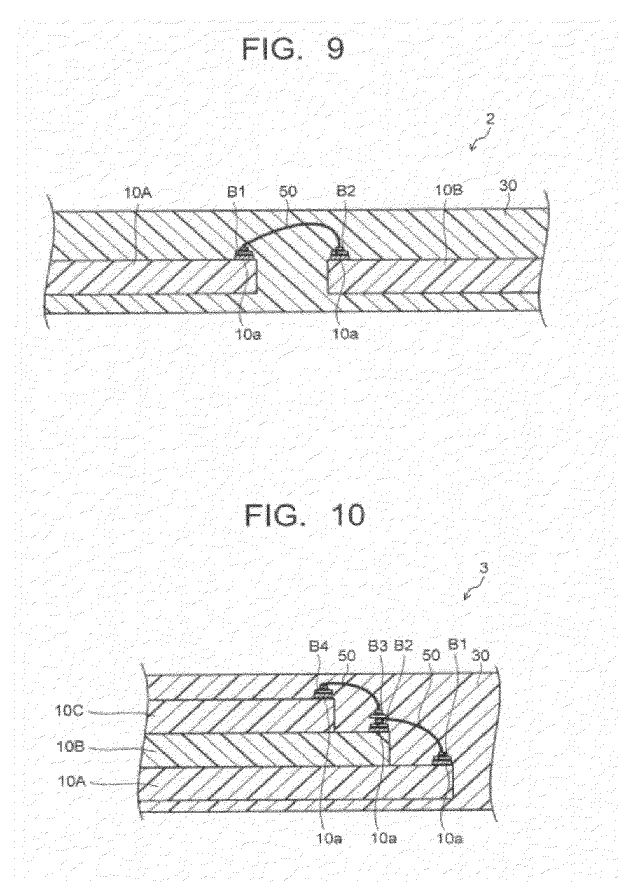

For example, application to a semiconductor device 2 of a multi-chip structure in which a plurality of semiconductor chips is aligned laterally is possible. In such a case, as shown in FIG. 9, a bonding wire looped from one semiconductor chip 10B is wedge-joined to a bump B1 formed on an electrode 10a of the other semiconductor chip 10A. The bump B1 can be formed by either the first action described with FIG. 4A to FIG. 4E or the second action described with FIG. 6A to FIG. 6G. Even in such a configuration, an effect the same as the effect described in the above-described embodiment can be obtained.

Application to a semiconductor 3 of a stack structure in which a plurality of semiconductor chips is stacked vertically is also possible. In such a case, as shown in FIG. 10, a bonding wire 50 looped from a semiconductor chip 10A is wedge-joined to a bump B2 formed on an electrode 10a of a semiconductor chip 10B, further, a bump B3 is formed on the bonding wire 50 having been wedge-joined to the bump B2, and the bonding wire 50 looped from the bump B3 is wedge-joined to a bump B4 formed on an electrode 10a of a semiconductor chip 10C. The bumps B2, B4 to which wedge-joining is performed can be formed either by the first action described with FIG. 4A to FIG. 4E or the second action described with FIG. 6A to FIG. 6G.

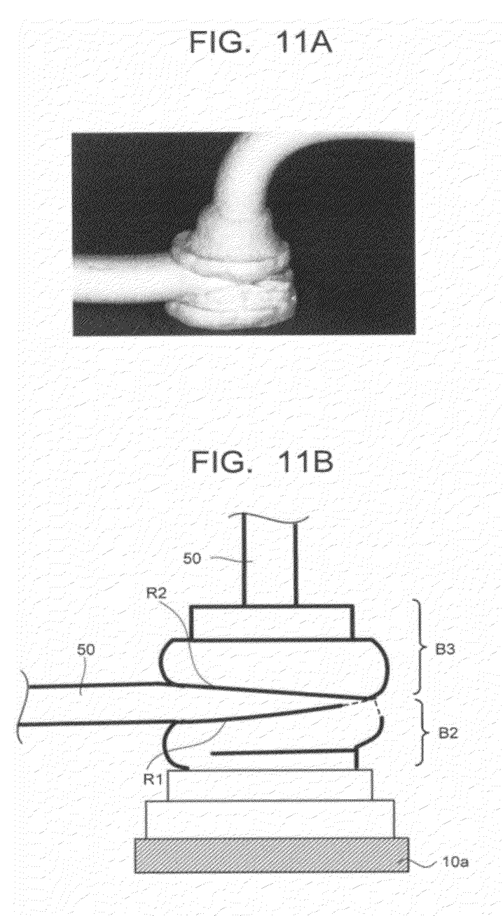

FIG. 11A is an SEM image of the bumps B2, B3 described with FIG. 10. FIG. 11B is an enlarged view of the bumps B2, B3 described with FIG. 10. It should be noted that, in FIG. 11B, in the bump B2 a part where a noble metal layer 50b covering a core 50a exists is indicated by a bold solid line while a part where the noble metal layer 50b does not exist is indicated by a broken line.

As shown in FIG. 11B, at least a part of an upper surface of the bump B2 is covered by the noble metal layer 50b and the bonding wire 50 is also covered by the noble metal layer 50b. Thus, when the bonding wire 50 is to be wedge-joined onto the bump B2, in a joined surface R1 of the upper surface of the bump B2 and the bonding wire 50, the noble metal layers 50b whose main components are noble metals are joined to each other, instead of the cores 50a whose main components are non-noble metals. When the bump B3 is to be joined onto the bonding wire 50 which has been wedge-joined onto the bump B2, in a joined surface R2 of a lower surface of the bump B3 and the bonding wire 50, the noble metal layers 50b whose main components are noble metals are joined to each other, instead of the cores 50a whose main components are non-noble metals, since the bonding wire 50 is covered by the noble metal layer 50b. Consequently, a sufficient joining strength can be obtained even in a case that joining described with FIG. 10 is performed, and reliability in joining is improved.

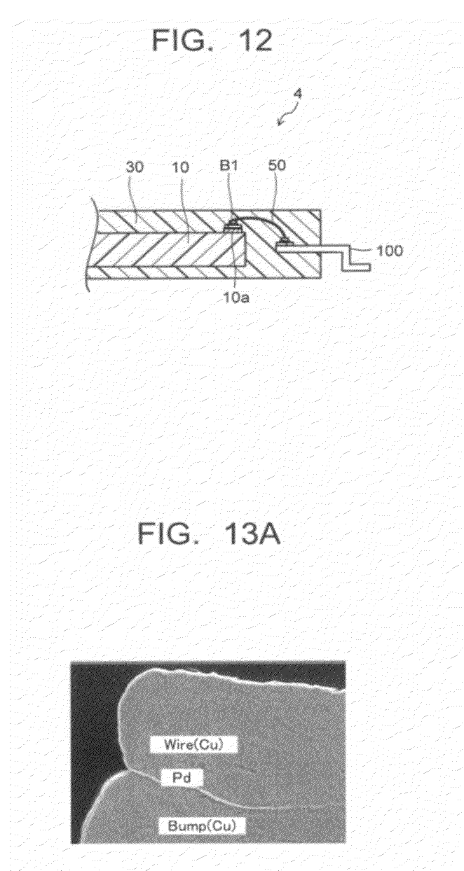

As shown in FIG. 12, the semiconductor chip 10 can be applied to a semiconductor device 4 mounted on a lead frame 100. In such a case, a bonding wire looped from the lead frame 100 is wedge-joined to a bump B1 formed on an electrode 10a of the semiconductor chip 10. Even in such a configuration, an effect the same as the effect described in the above-described embodiment can be obtained.

### EXAMPLE

Next, a test result in a case that what is called reverse bonding is performed by using the bonding wire 50 described in the above-described embodiment will be explained. In this example, a bonding wire whose copper (Cu) core is covered by a palladium (Pd) layer and whose outer diameter is 20 μm is used. It should be noted that an average thickness of the palladium layer is 100 nm. Further, as a comparative example, a test is performed also for a case that a copper bonding wire which is not covered by a noble metal and whose outer diameter is 20 μm is used.

In the tests, bonding is performed under the same conditions (for example, an action speed of a capillary, a pressing pressure, a temperature, and the like), and evaluation is done based on a ratio (defect rate=defect number/wire number) of occurrences of defects. Test results of the example and the comparative example will be represented in Table 1 below. It should be noted that the number of stopping of a bonding device during bonding is defined as the defect number. Further, an action of the capillary is the second action described with reference to FIG. 6A to FIG. 6G.

TABLE 1

| | Wire Number | Defect number | Defect rate |
|---|---|---|---|
| Example | 17676 | 0 | 0% |
| (Covered) | | | |
| Comparative | 160 | 4 | 2.5% |
| example | | | |
| (Not covered) | | | |

s represented in FIG. 1, in the example, 17676 wires are bonded, and the bonding device does not stop due to a poor condition during bonding. On the other hand, in the comparative example, during bonding of 160 wires, the bonding device stops four times due to poor conditions.

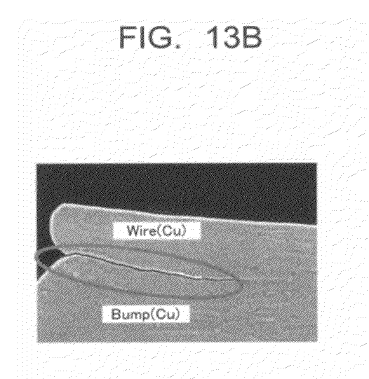

FIG. 13A shows a cross-sectional SEM image of a bump and a bonding wire according to the example. Further, FIG. 13B shows an SEM image of a bump and a bonding wire according to the comparative example. In the example shown in FIG. 13A, it is known that, since palladium being a noble metal existing in an interface between a bump and the bonding wire, the bump and the bonding wire are joined securely without a space. On the other hand in the comparative example shown in FIG. 13B, it is known that, since a noble metal not existing in an interface between a bump and the bonding wire, surfaces of the bump and the bonding wire are in oxidized states and joined, generating a space between the bump and the bonding wire, and leading to an occurrence of what is called wire peeling.

As described above, it is known that by using a bonding wire covered by palladium being a noble metal and pressing and joining the bonding wire in a manner to be folded at a time of forming a bump to be wedge-joined, joining reliability at a time of wedge-joining the bonding wire onto the bump can be improved.

While certain embodiments have been described, these embodiments have been presented by way of example only, and are not intended to limit the scope of the inventions. Indeed, the novel embodiment described herein may be embodiment in a variety of other forms; furthermore, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method for joining a bonding wire, the method comprising:
wedge-joining a bonding wire which has a core whose main component is a non-noble metal and a noble metal layer covering the core to a bump formed on an electrode of a semiconductor element via the noble metal layer.

2. The method according to claim 1,
wherein the bump is formed on the electrode of the semiconductor element in a manner that the bonding wire is folded.

3. The method according to claim 1, the method further comprising:
joining a bonding wire onto the bonding wire having been wedge-joined onto the bump, via the noble metal layer.

4. A semiconductor device, comprising:
a semiconductor chip which has an electrode;
a bump formed on the electrode of the semiconductor element; and
a bonding wire which has a core whose main component is a non-noble metal and a noble metal layer covering the core,
wherein the bonding wire is wedge-joined to the bump via the noble metal layer.

5. The device according to claim 4,
wherein the bump is formed on the electrode of the semiconductor element in a manner that the bonding wire is folded.

6. The device according to claim 4,
wherein a bonding wire is further joined on the bonding wire having been wedge-joined onto the bump, via the noble metal layer.

7. The device according to claim 4,
wherein a thickness of the noble metal layer is equal to or more than 10 nm.

8. A method for manufacturing a semiconductor device, the method comprising:
forming a bump on an electrode of a semiconductor chip in a manner to fold a bonding wire which has a core whose main component is a non-noble metal and a noble metal layer covering the core; and
wedge-joining the bonding wire to the bump via the noble metal layer.

9. The method according to claim 8, the method further comprising:
joining a bonding wire on the bonding wire having been wedge-joined onto the bump, via the noble metal layer.
